(19) United States
(12) Patent Application Publication
(10) Pub. No.: US 2013/0247994 A1
(43) Pub. Date: Sep. 26, 2013

(54) PHOTOVOLTAIC DEVICE

(71) Applicant: KABUSHIKI KAISHA TOYOTA CHUO KENKYUSHO, Nagakute-shi (JP)

(72) Inventors: Masaki HASEGAWA, Nagoya-shi (JP); Shinichi TAMURA, Nagakute-shi (JP); Takashi IKUNO, Nisshin-shi (JP); Tatsuo FUKANO, Nagoya-shi (JP); Shin TAJIMA, Nagoya-shi (JP)

(73) Assignee: KABUSHIKI KAISHA TOYOTA CHUO KENKYUSHO, Nagakute-shi (JP)

(21) Appl. No.: 13/838,129

(22) Filed: Mar. 15, 2013

(30) Foreign Application Priority Data
Mar. 26, 2012 (JP) 2012-070413
Feb. 21, 2013 (JP) 2013-032640

(51) Int. Cl. H01L 31/032

(52) U.S. Cl. CPC H01L 31/0326
USPC 136/265

(57) ABSTRACT

A photovoltaic device includes a light absorbing layer as a p-type semiconductor, a buffer layer, and a window layer. The light absorbing layer, the buffer layer, and the window layer are provided in this order. A film of a sulfide-based compound semiconductor containing Cu, Zn, Sn, and S is used as the light absorbing layer. In addition, the buffer layer includes a material having a composition of Zn₁₋ₓMgₓO (0<x≦0.4), and including a phase having a hexagonal crystal structure as a main component.

### CROSS REFERENCE TO RELATED APPLICATIONS

This application claims priority from Japanese Patent Application No. 2012-070413 filed on Mar. 26, 2012, and Japanese Patent Application No. 2013-032640 filed on Feb. 21, 2013.

### FIELD OF THE INVENTION

The present invention relates to a photovoltaic device, more particularly to a photovoltaic device having a buffer layer including Zn₁₋ₓMgₓO provided on a light absorbing layer including a sulfide-based compound semiconductor (CZTS-based compound semiconductor).

### BACKGROUND OF THE INVENTION

The photovoltaic device refers to a device that can convert photon energy to an electric signal through a certain physical phenomenon (photovoltaic conversion). A solar cell, which is a type of the photovoltaic device, can efficiently convert the energy of the solar illumination to electric energy.

Known semiconductors used for the solar cell include single crystalline Si, polycrystalline Si, amorphous Si, GaAs, InP, CdTe, CuIn₁₋ₓGaₓSe₂ (CIGS), and Cu₂ZnSnS₄ (CZTS).

Among them, chalcogenide compounds typified by CIGS and CZTS can each be formed into a cost-advantageous thin film due to a large light absorption coefficient thereof. In particular, a solar cell with CIGS as a light absorbing layer has relatively high conversion efficiency among thin-film solar cells, and sometimes exhibits conversion efficiency higher than that of a polycrystalline-Si solar cell (see Patent Document 1 and Patent Document 2, for example). However, CIGS disadvantageously contains an environmental-burden element and a rare element.

On the other hand, CZTS has a bandgap energy suitable for a solar cell (1.4 to 1.5 eV), and contains no environmental-burden element and no rare element.

A buffer layer is essentially provided in the solar cell including CICS or CZTS as the light absorbing layer. The buffer layer, which is formed between the light absorbing layer and a window layer, is estimated to be necessary for adjustment of a band profile and a hetero interface. The buffer layer is often formed by a chemical bath deposition (CBD) process in which CdS is often used for the buffer layer (see Patent Document 3 and Patent Document 4, for example).

A typical CdS buffer layer, however, contains cadmium which is a toxic substance. Moreover, a CZTS-based solar cell including the CdS buffer layer has low quantum efficiency in a short wavelength range. This is because the CdS layer absorbs the light in the short wavelength range.

To solve the problem, a material other than CdS can possibly be used for the buffer layer. However, each of existing thin-film solar cells, which includes a buffer layer containing no cadmium, generally exhibits low power generation efficiency.

### CITATION LIST

### Patent Document

[Patent Document 1] Japanese Unexamined Patent Application Publication No. 2000-323733.
[Patent Document 2] Japanese Unexamined Patent Application Publication No. 2004-281938.
[Patent Document 3] Japanese Unexamined Patent Application Publication No. 2011-146594.
[Patent Document 4] Japanese Unexamined Patent Application Publication No. 2011-146595.

### SUMMARY OF THE INVENTION

The problem that the invention is to solve is to suppress a reduction in quantum efficiency in a short wavelength range without using a buffer layer containing a toxic substance in a photovoltaic device having a light absorbing layer including a sulfide-based compound semiconductor.

To solve the above problem, a first photovoltaic device according to the present invention includes a light absorbing layer as a p-type semiconductor, a buffer layer, and a window layer,

wherein the light absorbing layer, the buffer layer, and the window layer are provided in this order,

the light absorbing layer is a film of a sulfide-based compound semiconductor containing Cu, Zn, Sn, and S, and

the buffer layer has a composition of Zn₁₋ₓMgₓO (0<x≦0.4) and includes a phase having a hexagonal crystal structure as a main component.

A second photovoltaic device according to the invention includes a light absorbing layer as a p-type semiconductor, a buffer layer, and a window layer,

wherein the light absorbing layer, the buffer layer, and the window layer are provided in this order,

the light absorbing layer is a film of a sulfide-based compound semiconductor containing Cu, Zn, Sn, and S, and the buffer layer has a composition of Zn₁₋ₓMgₓO (0<x<0.1).

When Zn₁₋ₓMgₓO (hexagonal Zn₁₋ₓMgₓO) is used for a buffer layer in a photovoltaic device having a light absorbing layer including a sulfide-based compound semiconductor, relatively high conversion efficiency is achieved. This is believed to be because

(1) the material for the buffer layer has a wide bandgap, thus improving power generation efficiency in a short wavelength range, and

(2) a conduction band offset as a difference between the lower end of the conduction band of the buffer layer and the lower end of the conduction band of the light absorbing layer is optimized.

Furthermore, Zn₁₋ₓMgₓO has a small environmental burden since it contains no toxic element.

### BRIEF DESCRIPTION OF THE DRAWINGS

FIG. 1 is a diagram illustrating a relationship between x and conversion efficiency of Zn₁₋ₓMgₓO (ZMO);

FIG. 2 is a diagram illustrating I-V characteristics of a cell including a ZMO buffer layer (Mg: 6 at %) prepared by a liquid phase process and I-V characteristics of a cell including a CdS buffer layer;

FIG. 3 is a diagram illustrating incident-photon-to-current conversion efficiency (IPCE) characteristics of each of the cell including the ZMO buffer layer (Mg: 6 at %) prepared by a liquid phase process and the cell including the CdS buffer layer;

FIGS. 4A and 4B illustrate XRD spectra in a low angle range (FIG. 4A) and in a high angle range (FIG. 4B) of each of ZMO (Mg: 30 at %) and ZnO (Mg: 0 at %) prepared by a liquid phase process;

FIG. 5 illustrates XRD spectra of each of ZMO (Mg: 10.0 at %) and ZnO (Mg: 0 at %) prepared by an ALD process; and

FIGS. 6A and 6B illustrate XRD spectra in a low angle range (FIG. 6A) and in a high angle range (FIG. 6B) of each of ZMO and ZnO (Mg: 0 at %) prepared by a co-sputtering process.

### DETAILED DESCRIPTION OF THE PREFERRED EMBODIMENTS

Hereinafter, an embodiment of the present invention will be described in detail.

### [1. Photovoltaic Device (1)]

A photovoltaic device according to a first embodiment of the invention includes a light absorbing layer as a p-type semiconductor, a buffer layer, and a window layer,

wherein the light absorbing layer, the buffer layer, and the window layer are provided in this order,

the light absorbing layer is a film of a sulfide-based compound semiconductor containing Cu, Zn, Sn, and S, and

the buffer layer has a composition of Zn₁₋ₓMgₓO (0<x≦0.4), and includes a phase having a hexagonal crystal structure as a main component.

### [1.1. Light Absorbing Layer]

The light absorbing layer is configured of a film of a sulfide-based compound semiconductor containing Cu, Zn, Sn, and S. The sulfide-based compound semiconductor containing such elements is a p-type semiconductor.

In the present invention, “sulfide-based compound semiconductor” refers to a semiconductor containing Cu₂ZnSnS₄ (CZTS) as base material (CZTS-based compound semiconductor).

In the invention, “sulfide-based compound semiconductor” includes not only the stoichiometric compound, but also all nonstoichiometric compounds, or includes all compounds containing Cu, Zn, Sn, and S as main components.

The sulfide-based compound semiconductor may exclusively contain Cu, Zn, Sn, and S, or may further contain another chalcogen element, any dopant, and/or any inevitable impurity.

The ratio between the metal elements contained in the sulfide-based compound semiconductor is not particularly limited, and may be appropriately selected for each purpose. To achieve high conversion efficiency, the ratio of Cu is preferably slightly smaller than the stoichiometric composition. In detail, the Cu/(Zn⁺ Sn) ratio (atomic ratio) is preferably 0.69 to 0.99, and more preferably 0.8 to 0.9.

The thickness of the light absorbing layer is not particularly limited, and is preferably selected to have an optimum value for each purpose. In general, an excessively small thickness of the light absorbing layer results in insufficient light absorption. On the other hand, an excessively large thickness of the light absorbing layer results in an increase in series resistance component.

The sulfide-based compound semiconductor has a large light absorption coefficient, thus allowing a reduction in thickness of the light absorbing layer. The thickness of the light absorbing layer is preferably 0.2 to 2.0 μm.

### [1.2 Buffer Layer]

The buffer layer is provided between the light absorbing layer and the window layer. The buffer layer provided between the light absorbing layer and the window layer secures excellent connection of the light absorbing layer to the window layer, resulting in improvement in power generation efficiency. In the first embodiment, the buffer layer has a composition of Zn₁₋ₓMgₓO (0<x≦0.4), and has a phase having a hexagonal crystal structure as a main component.

The ratio (x) of Mg contained in Zn₁₋ₓMgₓO (ZMO) has influence on the conversion efficiency of the photovoltaic device. High conversion efficiency is not achieved by a buffer layer including ZnO. To achieve high conversion efficiency, the ratio (x) of Mg must be more than 0. The ratio (x) of Mg is preferably 0.01 or more, and more preferably 0.05 or more.

On the other hand, an excessively high ratio (x) of Mg rather reduces the conversion efficiency. Hence, the ratio (x) of Mg must be 0.4 or less. The ratio (x) of Mg is preferably 0.20 or less, and more preferably 0.15 or less.

ZMO has a hexagonal crystal structure, a cubic crystal structure, or an amorphous structure. In the first embodiment, ZMO includes a phase having a hexagonal crystal structure as a main component.

The meaning of “a hexagonal crystal structure as a main component” is that among X-ray diffraction peaks derived from the buffer layer, the most intense peak is derived from hexagonal ZMO.

A buffer layer including hexagonal ZMO as a main component results in high conversion efficiency compared with a buffer layer including ZMO having another crystal structure as a main component.

The thickness of the buffer layer is not particularly limited, and is preferably selected to have an optimum value for each purpose. In general, if the thickness of the buffer layer is excessively small, electrons, which have been transferred from the light absorbing layer to the window layer, may return to the light absorbing layer for recombination, resulting in an increase in loss. On the other hand, an excessively large thickness of the buffer layer results in an increase in series resistance component. The thickness of the buffer layer is thus preferably 10 to 150 nm, and more preferably 30 to 150 nm.

### [1.3 Window Layer]

The window layer is provided on a surface of the buffer layer on a side far from the light absorbing layer. Specifically, these three components are provided in order of the light absorbing layer, the buffer layer, and the window layer. Light enters the window layer, passes through the buffer layer, and reaches the light absorbing layer. Hence, in the case where the layers are formed on a substrate, and if the substrate is formed of a non-light-transmissive material, the layers must be formed such that the light absorbing layer is located on a side near the substrate. On the other hand, if the substrate is formed of a light-transmissive material, the layers may be formed such that the window layer is located on a side near the substrate.

The window layer is a light-transmissive layer provided for collection of photocurrent generated by the photovoltaic effect. A material, which has a low resistance and transmits most light ranging from a visible region to a near-infrared region, is used for the window layer.

Examples of the materials for the window layer include Ga-doped Zn₁₋ₓMgₓO (ZMO:Ga), ZnO:B, ZnO:Al (AZO), In—Sn—O, In—Zn—O, SnO₂:Sb, TiO₂:Nb, and ZnO:Ga (GZO).

The thickness of the window layer is not particularly, limited, and is preferably selected to have an optimum value for each purpose. In general, excessively small thickness of the window layer results in a reduction in current collecting efficiency. On the other hand, excessively large thickness of the window layer results in an increase in light absorption. The thickness of the window layer is thus preferably 100 to 2000 nm.

### [1.4 Other Components]

The photovoltaic device according to the invention may further include a component other than the light absorbing layer, the buffer layer, and the window layer as necessary.

For example, a thin-film solar cell generally has a structure in which a bottom electrode, a light absorbing layer, a buffer layer, a window layer, and a top electrode are stacked in this order on a substrate. An additional layer may be provided between the adjacent layers.

The additional layer specifically includes

(1) an adhesion layer for improving adhesion between the substrate and the bottom electrode,

(2) a light scattering layer, which reflects incident light to improve the light absorbing efficiency of the light absorbing layer, provided near the top electrode with respect to the light absorbing layer,

(3) a light scattering layer provided near the substrate with respect to the light absorbing layer, and

(4) an antirefiection layer that reduces the reflected amount of incident light by the window layer to improve the light absorbing efficiency of the light absorbing layer.

In the invention, the materials of layers other than the light absorbing layer and the buffer layer are not particularly limited, and various materials may be used for each purpose.

In the case where the photovoltaic device is a solar cell, the materials for the layers other than the light absorbing layer, the buffer layer, and the window layer specifically include the following materials.

Examples of the material for the substrate include

(1) glass such as soda lime glass (SLG), law-alkali glass, non-alkali glass, quartz glass, Na-ion-implanted quartz glass, and sapphire glass,

(2) ceramics such as oxides including silica, alumina, yttria, and zirconia, and various Na-contained ceramics, and

(3) metals such as stainless steel, Na-contained stainless steel, Au, Mo, and Ti.

Examples of the material for the bottom electrode include Mo, In—Sn—O, In—Zn—O, ZnO:B, SnO₂:F, SnO₂:Sb, TiO₂:Nb, MoSi₂, stainless steel, ZnO:Al, and ZnO:Ga. In the case where a glass substrate is used as the substrate, Mo is preferred as the material for the bottom electrode in light of adhesion, electric conductivity, reflectance of incident light, and sulfurization resistance.

Examples of the material for the top electrode include Al, Cu, Ag, Au, and alloys each containing one or more of them. Such alloys specifically include an Al—Ti alloy, an Al—Mg alloy, an Al—Ni alloy, a Cu—Ti alloy, a Cu—Sn alloy, a Cu—Zn alloy, a Cu—Au alloy, an Ag—Ti alloy, an Ag—Sn alloy, an Ag—Zn alloy, and an Ag—Au alloy.

If a glass substrate is used as the substrate, and if Mo is used for the bottom electrode, examples of the material for the adhesion layer include Ti, Cr, Ni, W, and alloys each containing one or more of them.

Examples of the material for the light scattering layer provided above the light absorbing layer include oxides such as SiO₂ and TiO₂, and nitrides such as Si—N.

Examples of the material for the light scattering layer provided near the substrate with respect to the light absorbing layer include a layer having an irregular surface.

Examples of the material for the antireflection layer include (a) a transparent material having a smaller refractive index than that of the window layer, (b) an aggregate composed of transparent particles each having a sufficiently smaller size than a certain wavelength of sunlight, and (c) a material having spaces therein, each space having a sufficiently smaller size than a certain wavelength of sunlight. Specifically, (1) a thin film including MgF₂ or SiO₂, (2) a multilayer film including an oxide, a sulfide, a fluoride, and a nitride, and (3) fine particles each including an oxide such as SiO₂, are included.

### [2. Photovoltaic Device (2)]

A photovoltaic device according to a second embodiment of the invention includes a light absorbing layer as a p-type semiconductor, a buffer layer, and a window layer,

wherein the light absorbing layer, the buffer layer, and the window layer are provided in this order, the light absorbing layer is a film of a sulfide-based compound semiconductor containing Cu, Zn, Sn, and S, and the buffer layer has a composition of Zn₁₋ₓMgₓO (0<x<0.1).

### [2.1 Light Absorbing Layer]

Details of the light absorbing layer are similar to those in the first embodiment; hence, description of them is omitted.

### [2.2 Buffer Layer]

In the second embodiment, the buffer layer has a composition of Zn₁₋ₓMgₓ0 (0<x<0.1). In other words, the buffer layer may have any crystal structure as long as the ratio (x) of Mg is within the predetermined range. The buffer layer in the second embodiment is different in this point from the buffer layer in the first embodiment.

Other points of the buffer layer are similar to those in the first embodiment; hence, description of them is omitted.

### [2.3 Window Layer]

Details of the window layer are similar to those in the first embodiment; hence, description of them is omitted.

### [2.4 Other Components]

Details of the other components are similar to those in the first embodiment; hence, description of them is omitted.

### [3. Method of Manufacturing Photovoltaic Device]

The photovoltaic device according to the invention is produced by stacking the light absorbing layer, the buffer layer, the window layer, and other additional layers in a predetermined order. Description is now made on a method of manufacturing the photovoltaic device having a structure including the bottom electrode, the light absorbing layer, the buffer layer, the window layer, and the top electrode stacked in this order on the substrate. Any photovoltaic device having another stacked structure may be manufactured by a method similar to the following method except that a stacking order is altered.

### [3.1 Bottom-Electrode Formation Step]

First, the bottom electrode is formed on the substrate (bottom-electrode formation step). The process for forming the bottom electrode is not particularly limited, and any appropriate process may be used.

Specifically, the process for forming the bottom electrode includes a sputtering process, a vacuum deposition process, a pulsed laser deposition (PLD) process, a plating process, a chemical bath deposition (CBD) process, an electrophoretic deposition (EPD) process, a chemical vapor deposition (CVD) process, a spray pyrolysis deposition (SPD) process, a screen printing process, a spin coating process, and a nanoparticle deposition process.

In the case where a self-sustaining electrode is used, the bottom-electrode formation step may be omitted, i.e., the substrate may not be used.

### [3.2 Light-Absorbing-Layer Formation Step]

The light absorbing layer is then formed on the bottom electrode (light-absorbing-layer formation step). The process for forming the light absorbing layer including a sulfide-based compound semiconductor is not particularly limited, and any appropriate process may be used.

Examples of the process for forming the light absorbing layer include

(1) a process where a Cu—Zn—Sn precursor film or a Cu—Zn—Sn—S precursor film is formed on a surface of the substrate, and the precursor film is then sulfurized, and

(2) a process where a metal oxide thin-film containing Cu, Zn, and Sn is formed on a surface of the substrate, and the metal oxide film is then sulfurized.

The sulfurization is performed through heating of the precursor film under an H₂S atmosphere (for example, under a mixed-gas atmosphere of 5 to 20 vol % H₂S and N₂) or under coexistence of sulfur vapor. The heating temperature is about 500 to 600° C. Moreover, a variety of sulfide-based compound semiconductors having different compositions can be formed by varying the ratio between the metal elements contained in the precursor film.

### [3.3 Buffer-Layer Formation Step]

The buffer layer is then formed on the light absorbing layer (buffer-layer formation step). The buffer layer including ZMO may be formed by any appropriate process.

Examples of the process for forming the buffer layer including ZMO include

(1) a process where a solution, in which a zinc salt and a magnesium salt are dissolved, is applied onto a surface of the light absorbing layer, and the coating is then heat-treated in an oxygen atmosphere (liquid phase process),

(2) a process where the elements are deposited at a predetermined ratio on the surface of the light absorbing layer while supply of a source gas (one of an organic zinc compound gas and an organic magnesium compound gas), supply of a purge gas, and oxidization with oxygen plasma are repeated (atomic layer deposition (ALD) process), and

(3) a process where Zn and Mg are co-sputtered with a ZnO target and an MgO target (co-sputtering process).

The crystal structure of ZMO is affected by a formation process of ZMO. For example, in the case where the liquid phase process or the ALD process is used, a buffer layer mainly including hexagonal ZMO is produced. On the other hand, in the case where the co-sputtering process is used, a buffer layer mainly including cubic ZMO or amorphous ZMO is produced. To achieve high conversion efficiency, the liquid phase process or the ALD process is more preferable than the co-sputtering process or the CBD process as a formation process of ZMO.

In each process, ZMO having different ratios (x) of Mg can be manufactured by varying the ratio of Zn to Mg in a source material.

In the case where the buffer layer is formed by the liquid phase process, any type of zinc salt and any type of magnesium salt may be used without limitation, as long as the zinc or magnesium salt is soluble in a solvent.

Examples of the zinc salt include zinc acetate.

Examples of the magnesium salt include magnesium acetate.

The heat treatment is performed in an oxygen atmosphere in order to convert the zinc salt and the magnesium salt to an oxide. The heat treatment may be performed under any condition of temperature and time, as long as the salt can be converted to the oxide on that condition. The heat treatment temperature is typically 200 to 600° C., and the heat treatment time is typically 10 to 100 min.

In the case where the buffer layer is formed by the ALD process, any organic zinc compound or any organic magnesium compound may be used as long as the compound can be supplied in a form of a source gas, and can be decomposed by oxygen plasma.

Examples of the organic zinc compound include diethyl zinc, zinc chloride, dimethyl zinc, and zinc acetate.

Examples of the organic magnesium compound include bis(ethylcyclopentadienyl)magnesium, bis(pentamethylcyclopentadienyl)magnesium, bis(cyclopentadienyl)magnesium, and 2,2,6,6-tetramethyl-3,5-heptanedionato magnesium.

Any substrate temperature during the film formation may be set without limitation, as long as the source gas can be decomposed by oxygen plasma. The substrate temperature is typically 100 to 230° C., and preferably 150 to 200° C.

### [3.4 Window-Layer Formation Step]

The window layer is then formed on the buffer layer (window-layer formation step). The process for forming the window layer is not particularly limited, and any appropriate process may be used. Details of the formation process of the window layer are similar to those in the bottom-electrode formation step; hence, description of them is omitted.

### [3.5 Top-Electrode Formation Step]

The top electrode is then formed on the window layer (top-electrode formation step). The process for forming the top electrode is not particularly limited, and any appropriate process may be used. Details of the formation process of the top electrode are similar to those in the bottom-electrode formation step; hence, description of them is omitted.

### [3.6 Other Steps]

The photovoltaic device may further include any appropriate layer other than the bottom electrode, the light absorbing layer, the buffer layer, the window layer, and the top electrode.

The process for forming such an additional layer is not particularly limited, and any appropriate process may be used. Details of the formation process of the additional layer are similar to those in the bottom-electrode formation step; hence, description of them is omitted.

### [4. Effect of Photovoltaic Device]

It is known that the conversion efficiency of the photovoltaic device is improved through interposition of a buffer layer between the light absorbing layer and the window layer. This is believed to be because, if a buffer layer having an appropriate bandgap is provided between the light absorbing layer and the window layer, a difference (conduction band offset) between an energy level at the lower end of the conduction band of the light absorbing layer and an energy level at the lower end of the conduction band of the buffer layer is optimized, and thereby suppression of carrier recombination and smooth transfer of carriers from the light absorbing layer to the window layer are concurrently achieved.

It is known that if CdS is used for the buffer layer in the photovoltaic device having the light absorbing layer including a sulfide-based compound semiconductor, the photovoltaic device exhibits relatively high conversion efficiency. However, CdS is limited in improvement in conversion efficiency due to its low quantum efficiency in a short wavelength range. In addition, CdS disadvantageously contains Cd having a large environmental burden.

In contrast, if Zn₁₋ₓMgₓO (hexagonal Zn₁₋ₓMgₓO) is used for the buffer layer in the photovoltaic device having the light absorbing layer including a sulfide-based compound semiconductor, the photovoltaic device exhibits relatively higher conversion efficiency. This is believed to be because

(1) the material for the buffer layer has a wide bandgap, thus improving power generation efficiency in the short wavelength range, and

(2) a conduction band offset as a difference between the lower end of the conduction band of the buffer layer and the lower end of the conduction band of the light absorbing layer is optimized.

Furthermore, Zn₁₋ₓMgₓO has just a small environmental burden since it contains no toxic element.

### EXAMPLES

### Examples 1 to 3 and Comparative Example 2

### 1. Sample Preparation

### 1.1 Production of Solar Cell with ZMO as Buffer Layer (Examples 1 to 3)

A solar cell was produced according to the following procedure.

(1) A Mo film was formed by a sputtering process into a back (bottom) electrode on a glass substrate (25 mm×25 mm).

(2) ZnS, SnS, and Cu were deposited to be stacked in this order on the Mo film by a sputtering process so that a CZTS precursor was formed.

(3) The precursor was sulfurized to synthesize CZTS. The sulfurization was performed under a condition of 570° C. for 40 min in 20% H₂S+N₂ gas atmosphere at atmospheric pressure.

(4) An ethanolamine solution (solvent: 2-methoxy ethanol, and total metal ion concentration: 0.75 M) containing zinc acetate and magnesium acetate was applied by spin coating onto CZTS. The coating was then heat-treated to produce a Zn₁₋ₓMgₓO (x=0.2 to 0.6) film. The heat treatment was performed under a condition of 300° C. for 20 min in oxygen atmosphere at atmospheric pressure.

(5) A ZnO:Ga film was formed on the ZMO film by a sputtering process to produce the window layer.

(6) A comb-like electrode including an Al film was formed on the ZnO:Ga film by a vapor deposition process.

(7) The window layer, the buffer layer, and the CZTS layer were scribed to produce 5×5=25 cells.

### 1.2 Production of Solar Cell with CdS as Buffer Layer (Comparative Example 2)

A solar cell was produced in the same manner as Example 1 except that a CdS buffer layer was formed by a CBD process.

### 2. Test Method

### 2.1 Solar Cell Characteristics

The produced solar cell was subjected to evaluation of short-circuit current density (J_{sc}), open circuit voltage (V_{oc}), a fill factor (F.F.), and conversion efficiency (E_{ff}). A solar simulator was used for the measurement. The measurement was started immediately after a solar cell was irradiated with pseudo sunlight of Air Mass 1.5 (AM 1.5), and was completed in about 20 sec.

A relationship represented by Formula (I) is established between the conversion efficiency (E_{ff}), the open circuit voltage (V_{oc}), the short-circuit current density (J_{sc}), and the fill factor (F.F.).

E_{ff}=Vₒₓ×J_{sc}×F.F. (1)

### 2.2 X-Ray Diffraction

A ZMO film was formed on a glass substrate by a liquid phase process similar to the above. The substrate having the ZMO film thereon was subjected to X-ray diffraction analysis.

### 3. Results

### 3.1 Solar Cell Characteristics

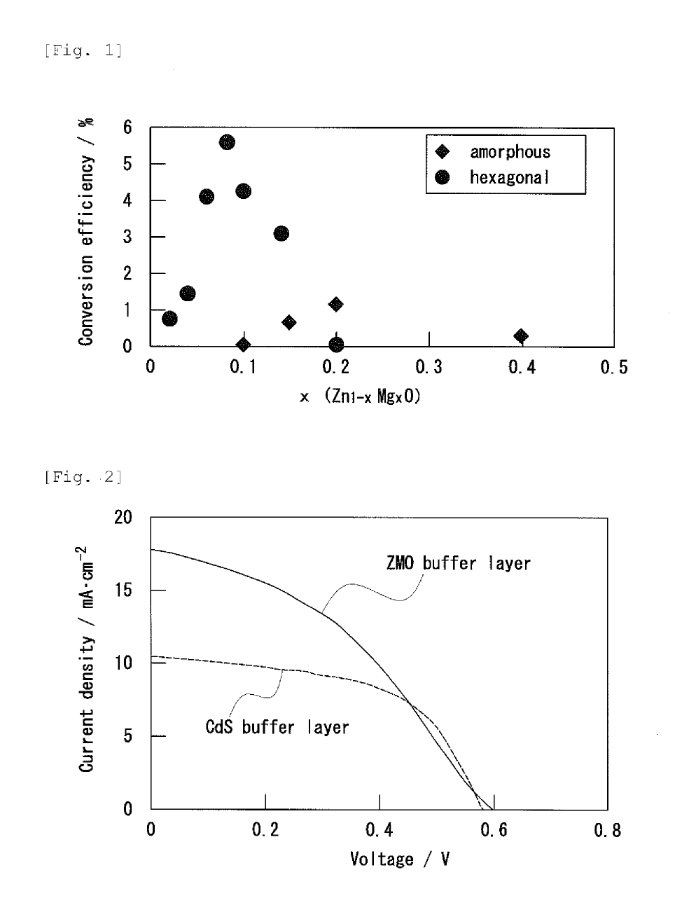

Table 1 shows the conversion efficiency, the short-circuit current density, the open circuit voltage, and the fill factor. FIG. 1 illustrates a relationship between x and the conversion efficiency of Zn₁₋ₓMgₓO. In addition, Table 1 and FIG. 1 each collectively show results on a solar cell produced by an ALD process (Examples 4 to 8 and Comparative example 1) described later. Table 1 and FIG. 1 reveal the following findings.

(1) The cell including the ZMO buffer layer prepared by the liquid phase process or the ALD process exhibits the maximum conversion efficiency at an x of about 0.08.

(2) Each cell including a ZMO buffer layer prepared by the liquid phase process or the ALD process with an x of 0.02 to 0.2 exhibits conversion efficiency of 0.07% or more.

(3) Each cell including a ZMO buffer layer prepared by the liquid phase process or the ALD process with an x of 0.06 to 0.1 exhibits conversion efficiency equal to or higher than that of a cell including a CdS buffer layer.

(4) Each cell including a ZMO buffer layer prepared by the liquid phase process or the ALD process with an x of 0.06 to 0.1 exhibits conversion efficiency of 4% or more.

(5) Each cell including a ZMO buffer layer prepared by the sputtering process with an x of 0.1 or more exhibits conversion efficiency of about 1% at the maximum.

TABLE 1

| | Formation | | Crystal | | | | |
|---|---|---|---|---|---|---|---|
| | process of | x | structure of | Conversion | Jsc | | |
| No. | buffer layer | (Zn₁₋ₓMgₓO) | ZMO | efficiency % | mA/cm² | Voc V | FF |
| Comparative | ALD | 0.000 | Hexagonal | <0.01 | — | — | — |
| Example 1 | | | | | | | |
| Example 1 | Liquid phase | 0.020 | Hexagonal | 0.77 | 8.00 | 0.30 | 0.32 |
| Example 2 | Liquid phase | 0.040 | Hexagonal | 1.43 | 9.30 | 0.48 | 0.32 |
| Example 3 | Liquid phase | 0.060 | Hexagonal | 4.12 | 17.70 | 0.59 | 0.39 |
| Example 4 | ALD | 0.083 | Hexagonal | 5.60 | 17.10 | 0.63 | 0.52 |
| Example 5 | ALD | 0.100 | Hexagonal | 4.27 | 13.70 | 0.63 | 0.50 |
| Example 6 | ALD | 0.140 | Hexagonal | 3.13 | 15.70 | 0.57 | 0.35 |
| Example 7 | ALD | 0.200 | Hexagonal | 0.07 | 16.00 | 0.19 | 0.22 |
| Example 8 | ALD | 0.300 | Hexagonal | <0.01 | — | — | — |
| Comparative | CBD | CdS | — | 3.32 | 10.42 | 0.58 | 0.55 |
| Example 2 | | | | | | | |
| Comparative | Sputtering | 0.100 | Amorphous | 0.04 | 6.00 | 0.03 | 0.24 |
| Example 3 | | | | | | | |
| Comparative | Sputtering | 0.150 | Amorphous | 0.65 | 8.60 | 0.22 | 0.35 |
| Example 4 | | | | | | | |
| Compararive | Sputtering | 0.200 | Amorphous | 1.16 | 8.40 | 0.57 | 0.25 |
| Example 5 | | | | | | | |
| Comparative | Sputtering | 0.400 | Amorphous | 0.30 | 4.10 | 0.25 | 0.30 |
| Example 6 | | | | | | | |

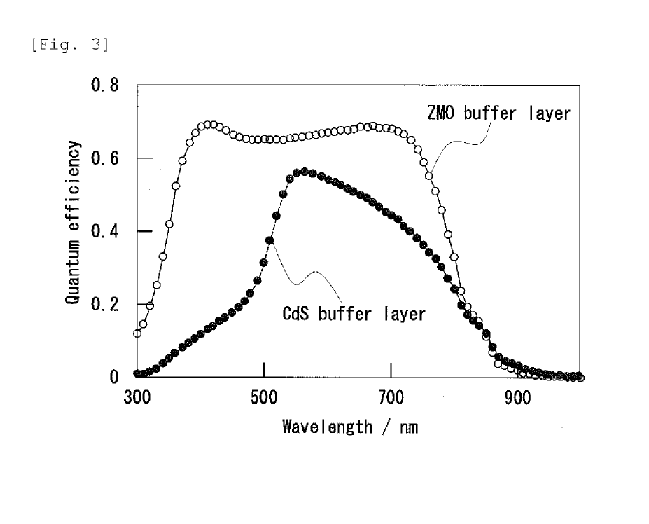

FIG. 2 illustrates characteristics of a cell including a ZMO buffer layer (Mg: 6 at %) prepared by the liquid phase process and I-V characteristics of a cell including a CdS buffer layer. FIG. 2 reveals that the cell including the ZMO buffer layer prepared by the liquid phase process exhibits increased short-circuit current density (an intersection (voltage=0) of the I-V curve with the vertical axis) in correspondence to improvement in quantum efficiency.

FIG. 3 illustrates incident-photon-to-current conversion efficiency (IPCE) characteristics of each of the cell including the ZMO buffer layer (Mg: 6 at %) prepared by the liquid phase process and the cell including the CdS buffer layer. FIG. 3 reveals that the cell including ZMO prepared by the liquid phase process as the buffer layer material exhibits improved quantum efficiency in a range of light having short wavelengths (300 to 500 nm) compared with the cell including the CdS buffer layer. The reason for this is believed to be as follows: since ZMO has a wide bandgap, light in the short wavelength range can reach the CZTS light absorbing layer without being absorbed by the buffer layer.

### 3.2 X-Ray Diffraction

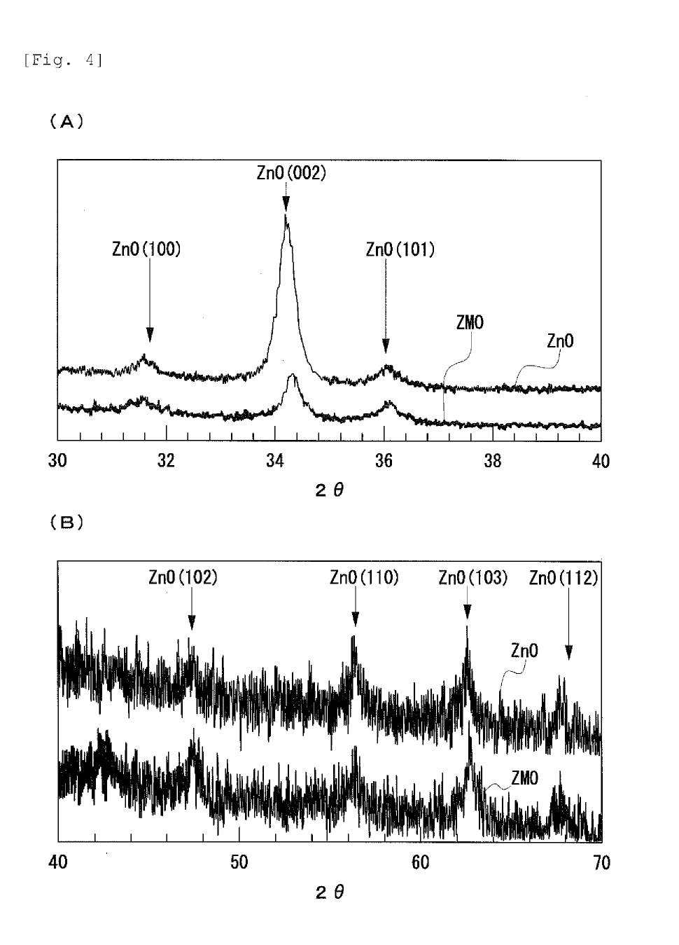

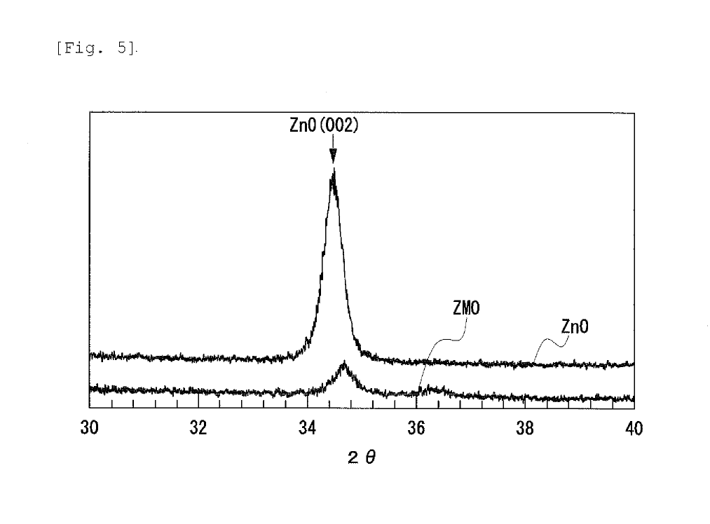

FIGS. 4A and 43 illustrate XRD spectra in a low angle range (FIG. 4A) and in a high angle range (FIG. 43) of each of ZMO (Mg: 30 at %) and ZnO (Mg: 0 at %) prepared by the liquid phase process.

In the XRD spectra of each of ZMO and ZnO prepared by the liquid phase process, although peaks corresponding to hexagonal ZnO (the stable structure of ZnO) are observed, no peak corresponding to cubic MgO (the stable structure of MgO) and no peak corresponding to cubic ZMO are observed. It is believed that the ZMO has a structure where a Zn site is substituted by Mg while a hexagonal structure of ZnO is maintained. In addition, it is guessed that ZMO with Mg content of less than 30 at % also has the hexagonal ZnO structure.

### Examples 4 to 8 and Comparative Example 1

### 1. Sample Preparation

A solar cell was produced according to the following procedure.

(1) An Mo film was formed by a sputtering process into a back (bottom) electrode on a glass substrate (25 mm×25 mm).

(2) ZnS, SnS, and Cu were deposited to be stacked in this order on the Mo film by a sputtering process so that a CZTS precursor was formed.

(3) The precursor was sulfurized to synthesize CZTS. The sulfurization was performed under the condition of 580° C. for 10 min in 20% H₂S+N₂ gas atmosphere at atmospheric pressure.

(4) A ZMO (x=0 to 0.30) film was synthesized from diethyl zinc and bis(ethylcyclopentadienyl)magnesium as source materials by an ALD process using oxygen plasma. The substrate temperature was 200° C. during film formation.

(5) A ZnO:Ga film was formed on the ZMO film by a sputtering process to produce the window layer.

(6) A comb-like electrode including an Al film was formed on the ZnO:Ga film by a vapor deposition process.

(7) The window layer, the buffer layer, and the CZTS layer were scribed to produce 5×5=25 cells.

### 2. Test Method and Results

Each of a ZMO film and a ZnO film was formed on a glass substrate by the ALD process. The substrate having such a film thereon was subjected to X-ray diffraction analysis. FIG. 5 illustrates XRD spectra of each of ZMO (Mg: 10.0 at %) and ZnO (Mg: 0 at %) prepared by the ALD process.

In the XRD spectra of each of ZMO and ZnO prepared by the ALD process, although a peak corresponding to hexagonal ZnO (the stable structure of ZnO) is observed, no peak corresponding to cubic MgO (the stable structure of MgO) and no peak corresponding to cubic ZMO are observed. It is believed that the ZMO has a structure where a Zn site is substituted by Mg while a hexagonal structure of ZnO is maintained.

### Comparative Examples 3 to 6

### 1. Sample Preparation

A solar cell was produced in the same manner as Example 1 except that a ZMO film (x≧0.1) was formed by a co-sputtering process using a ZnO target and an MgO target.

### 2. Test Method and Results

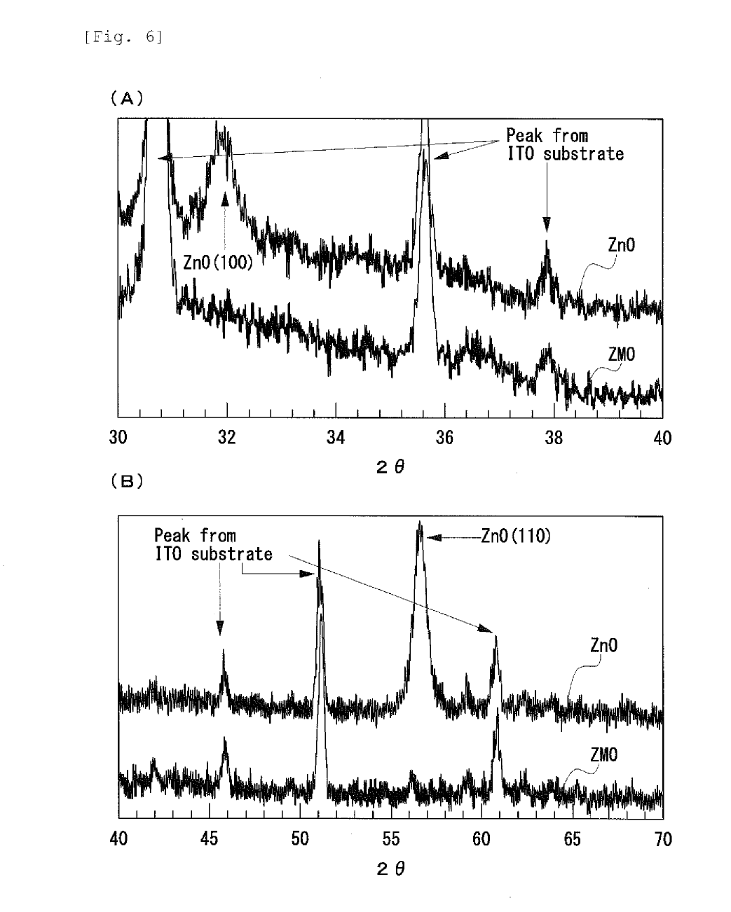

Each of a ZMO film and a ZnO film was formed on an ITO substrate by the co-sputtering process. The substrate having such a film thereon was subjected to X-ray diffraction analysis. FIGS. 6A and 6B illustrate XRD spectra in a low angle range (FIG. 6A) and in a high angle range (FIG. 6B) of each of ZMO and ZnO (Mg: 0 at %) prepared by the co-sputtering process.

In the XRD spectra of each of ZMO and ZnO prepared by the co-sputtering process, although a peak corresponding to hexagonal ZnO (the stable structure of ZnO) is observed with regard to ZnO, no peak corresponding to hexagonal ZnO is observed with regard to ZMO. It is believed that the ZMO has an amorphous structure rather than the hexagonal ZnO structure.

Although the embodiments of the invention have been described in detail hereinbefore, the invention should not be limited thereto, and various modifications or alterations thereof may be made within the scope without departing from the spirit of the invention.

The photovoltaic device according to the invention can be used for a thin-film solar cell, a photoconductive cell, a photodiode, a phototransistor, and a sensitized solar cell, for example.

What is claimed is:

1. A photovoltaic device including a light absorbing layer as a p-type semiconductor, a buffer layer, and a window layer,
wherein the light absorbing layer, the buffer layer, and the window layer are provided in this order,
the light absorbing layer is a film of a sulfide-based compound semiconductor containing Cu, Zn, Sn, and S, and
the buffer layer has a composition of Zn₁₋ₓMgₓO (0<x≦0.4), and includes a phase having a hexagonal crystal structure as a main component.

2. The photovoltaic device according to claim 1, wherein x satisfies 0.01≦x≦0.20.

3. The photovoltaic device according to claim 1, wherein x satisfies 0.05≦x≦0.15.

4. A photovoltaic device including a light absorbing layer as a p-type semiconductor, a buffer layer, and a window layer,
wherein the light absorbing layer, the buffer layer, and the window layer are provided in this order,
the light absorbing layer is a film of a sulfide-based compound semiconductor containing Cu, Zn, Sn, and S, and the buffer layer has a composition of Zn₁₋ₓMgₓO (0<x<0.1).
